(19) United States
(12) Patent Application Publication
(10) Pub. No.: US 2008/0309318 A1
(43) Pub. Date: Dec. 18, 2008

(54) Method and Device for Determining the Characteristics of the Voltage of an Electrical Installation

(75) Inventors: Guy Ross, Beloeil (CA); Marc Mihailovic, Rougemont-le-Chateau (FR)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FAMECA, Rixheim (FR)

(21) Appl. No.: 11/815,077

(22) PCT Filed: Dec. 14, 2005
(86) PCT No.: PCT/FR05/51085

§ 371 Date: Jul. 30, 2007

(30) Foreign Application Priority Data
Jan. 31, 2005 (FR) 0550274

(51) Int. Cl. G01R 31/02

(52) U.S. Cl. 324/72

(57) ABSTRACT

The invention relates to a method of determining the characteristics of the voltage of an electrical installation which is powered by a generator. The inventive method comprises the following steps consisting in: generating at least one electrical disturbance between at least two points of an electric circuit, which are separated by a dielectric layer; observing a first electric current at the terminals of a first impedance; bringing an electrode into contact with a point of the electrical installation; observing a second electric current at the terminals of a second impedance; observing the change in the first electric current at the terminals of the first impedance; and determining the characteristics of the voltage of the installation from the change in the first electric current and the characteristics of the second electric current. The invention also relates to a device which is used to implement said method.

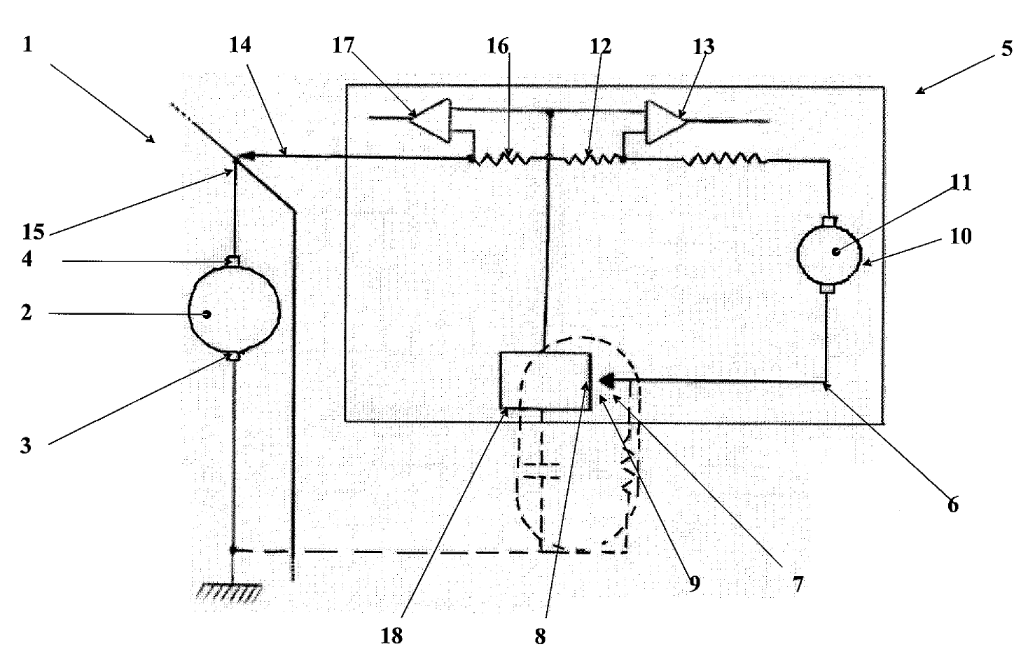

### BACKGROUND OF THE INVENTION

(1) Field of the Invention

The present invention relates to a method for determining the characteristics of the electric voltage of an electrical installation that is powered by a generator. The invention also relates to a device used to implement this method.

The invention regards the field of the design and manufacture of devices for detecting the voltage present at the level of an electrical installation.

(2) Description of the Prior Art

There are already known devices for detecting the voltage, which adopt e.g. the form of a resistive-type sensor, which, for a proper operation, requires being connected to the earth (or the mass of the electrical installation) through a wire. The presence of such a wired connection has a number of drawbacks, in particular in the event of an intervention on a high-voltage line located at a high height.

Such a detection device is indeed usually located at the end of an insulating pole handled by an operator, so that, in order to connect this device to the earth, it is absolutely required to have a wire of a large length and a heavy weight that is to be brought to the site, namely by carrying it by hand.

According to another drawback, this connecting wire should be fixed in a firm and secure way to the earth (or the mass of the installation) through an appropriate connecting organ. The connection and disconnection should comply with a strict security procedure. Any unexpected disconnection of this connecting organ while the detecting device is into contact with the energized installation will indeed cause the latter to be at a particularly high, even maximum, potential, which represents a substantial risk for the operator. This also applies in the event of breaking of the wire the end of which that remains connected is at a particular high, even maximum, potential.

Still another drawback is that such a resistive device has a not inconsiderably weak resistive element. The failure of the latter can cause a short-circuiting of the whole installation one wants to characterize.

There are also known capacitive-type devices that do not require any wired connection to the earth or the mass of the installation. However, such unipolar devices of this design can only detect alternating voltages, direct voltages being excluded.

### SUMMARY OF THE INVENTION

The present invention pretends to be capable of coping with the drawbacks of the devices of the state of the art through, on the one hand, a unipolar-type device designed capable of measuring both direct and alternating voltages and, on the other hand, a method implemented by means of such a device.

To this end, the invention relates to a method for determining the characteristics of the electric voltage of an electric installation powered by a generator. This method is characterized in that it consists in:
generating at least one electrical disturbance between at least two points of an electric circuit separated by a dielectric layer, this through a voltage generator associated with this electric circuit;
measuring, at the terminals of a first impedance this electric circuit includes, a first electric current the creation of which is caused by the electrical disturbance or disturbances generated;
then, bringing into contact an electrode associated with this electric circuit with a point of the electrical installation;
measuring, at the terminals of a second impedance this electric circuit includes and associated with this electrode, a second electric current created through this bringing into contact;
measuring the evolution of the first electric current at the terminals of the first impedance due to this bringing into contact;
determining the characteristics of the electric voltage of the installation based, on the one hand, on the evolution of the first electric current measured and, on the other hand, on the characteristics of the second electric current measured.

The invention also relates to a device for determining the characteristics of the voltage of an electrical installation. This device is characterized in that it includes:
means for generating at least one electrical disturbance between at least two points of an electric circuit this device includes and which are separated by a dielectric layer;
means for measuring, at the terminals of a first impedance this electric circuit includes, a first electric current the creation of which is caused by the electrical disturbance or disturbances generated as well as the evolution of this first electric current;
an electrode, associated with this electric circuit, aimed at being brought into contact with a point of the electrical installation;
means for measuring, at the terminals of a second impedance the electric circuit includes and associated with said electrode, a second electric current created due to this bringing into contact;
means for determining the characteristics of the electric voltage of the installation based, on the one hand, on the evolution of the first electric current measured and, on the other hand, on the characteristics of the second electric current measured.

The advantages of the present invention consist in that the device does not require any wired connection to the earth or to another point of the controlled electrical installation.

In addition, the invention allows determining, on the one hand, the state of voltage (presence or absence of voltage), on the other hand, the type of voltage (alternating or direct) and, still on the other hand, the level of voltage of the electrical installation.

Further objects and advantages of the present invention will become clear during the following description relating to embodiments, which are given only by way of indicative and non-restrictive examples.

### BRIEF DESCRIPTION OF THE DRAWINGS

This description will be better understood when referring to the attached drawing, in which the single FIGURE corresponds to a schematic view of the device according to the invention, connected to the installation the characteristics of the electric voltage of which should be determined.

### DETAILED DESCRIPTION OF THE PREFERRED EMBODIMENTS

The invention relates to the field of the detection, even of the determination, of the characteristics of an electric voltage present at the level of an electrical installation 1 powered by a generator 2, including several terminals 3, 4, one 3 of which is, as the case may be, connected to the earth (attached FIGURE) or floating.

The present invention will find a very particular application within the framework of fixed electrical installations, in particular of high-voltage, even very high-voltage electrical installations, namely electrified lines, however without the present invention being in any way limited thereto.

The invention also relates, on the one hand, to a method for determining the characteristics of the electric voltage of such an electrical installation 1 and, on the other hand, to a device 5 for determining the characteristics of the electric voltage of such an electrical installation 1, such a device 5 being, in particular, designed capable of implementing said method.

As can be seen in the attached FIGURE, this device 5 includes an electric circuit 6 at the level of which are defined at least two points 7, 8 separated by a dielectric layer 9 that has, on the one hand, a capacitance Ct and, on the other hand, a resistor Rt. In this respect, it should be noted that this dielectric layer 9 can, for example and preferably, be formed by a layer of air.

This device 5 also includes means 10 for generating at least one electrical disturbance between at least two of the above-mentioned points 7, 8 of the electrical circuit 6 and separated by such a dielectric layer 9. To this end, these means 10 are connected, as the case may be, directly or indirectly to at least these two points 7, 8.

In this respect, it should be noted that the means 10 for generating at least one such electrical disturbance are formed by means capable of generating a particular state of the material, namely a plasma, between at least two points 7, 8 of the electric circuit 6, thus at the level of said dielectric layer 9.

According to a particular embodiment of the invention, these means 10 for generating at least one electrical disturbance are formed by means capable of generating at least one electric are between at least two points 7, 8 of the electric circuit 6.

As can be seen on the attached FIGURE, the means 10 for generating at least one electrical disturbance between at least two points 7, 8 of the circuit 6 are preferably connected, on the one hand and directly, to one 7 of these points 7, 8 and, on the other hand and indirectly, to another one 8 of these points 7, 8.

An additional feature consists in that the means 10 for generating at least one electrical disturbance between at least two of these points 7, 8 are connected, directly or indirectly, to one or several terminals defined at the level of a first point 7 of the circuit 6, namely formed by a first leg this circuit 6 includes, and/or to one or several terminals defined at the level of a second point 8 of this circuit 6, namely formed by a second leg of this circuit 6.

A particular embodiment consists in connecting these means 10, at the level of this first point 7 and/or at the level of this second point 8, to a plurality of terminals.

The presence of a plurality of these terminals allows generating at least one electric disturbance between, one the one hand, one or several terminals defined at the level of the first point 7 of the circuit 6 and, on the other hand, one or several terminals defined at the level of the second point 8 of this circuit 6.

In this respect, it should be noted that the plurality of terminals defined at the level of the first point 7 and/or the second point 8 allow generating a plurality of disturbances (namely one disturbance per terminal), which result into creating a plurality of induced currents in the first impedance 12.

A particular embodiment of the invention then consists in generating a positive disturbance and/or a negative disturbance (in particular a positive electric arc and/or a negative electric arc) between, on the one hand, one or several terminals (preferably a plurality of terminals) defined at the level of the first point 7 and, on the other hand, a second point 8, namely one or several terminals of this second point 8.

Such an embodiment will find a very particular interest in the case of a direct-current installation for which it is then possible to determine the polarity of the controlled point of such an installation.

This embodiment will also find an interest in the case of an alternating-current installation, in particular within the framework of very high voltages or in a disturbed environment, in which conditions it is particularly difficult to determine the characteristics of an electric voltage through the devices of the state of art.

According to an additional feature, the means 10 for generating at least one electrical disturbance are formed by a voltage generator 11 associated with the electric circuit 6 (or the latter 6 includes) and connected (in particular, directly) to one 7 of the points 7, 8 between which such an electrical disturbance is generated.

Another feature consists in that the electric circuit 6 also includes a first impedance 12 having, on the one hand, a first terminal connected to the means 10 for generating at least one electrical disturbance between at least two points 7, 8 of the circuit 6. This first impedance 12 has, on the other hand, a second terminal connected to one 8 of the points 7, 8 of the circuit 6, on the one hand, between which 7, 8 at least one electrical disturbance is generated and, on the other hand, other than the one 7 connected to the means 10 for generating at least one such disturbance. This being said, said means 10 are then indirectly connected to this point 8 and through said impedance 12.

The device 5 then includes means 13 for measuring, at the terminals of this first impedance 12, on the one hand, a first electric current the creation of which is caused by the electrical disturbances generated by the means 10 and, on the other hand, the evolution of this first electric current. In this respect, it should be noted that this first electric current created depends on the impedances (capacitance Ct and resistor Rt of the above-mentioned dielectric layer 9).

Another feature of the invention consists in that the device 5 includes an electrode 14, associated with the electric circuit 6, and aimed at being brought into contact with a point 15 of the electrical installation 1 at the level of which the characteristics of the electric voltage are determined.

As can be seen on the attached FIGURE, the electric circuit 6 of this device 5 also includes a second impedance 16 having, on the one hand, a first terminal connected to said electrode 14 and, on the other hand, a second terminal connected to one 8 of the points 7, 8 of the circuit 6, on the one hand, between which 7, 8 at least one electrical disturbance is generated and, on the other hand, other than the one 7 connected to the means 10 for generating at least one such disturbance.

The device 5 according to the invention then includes means 17 for measuring, at the terminals of this second impedance 16 (the electric circuit 6 includes and which is associated with said electrode 14), a second electric current created in the electric circuit 6 due to bringing this electrode 14 into contact with the point 15 of the electrical installation 1.

According to another feature of the invention, the device 5 includes means (not shown) for determining the characteristics of the electric voltage of the installation 1 based, on the one hand, on the evolution of the first electric current measured through the means 13 and, on the other hand, on the characteristics of the second electric current measured through the means 17.

As evoked above, the first 12 and/or second 16 impedances are connected to one 8 of the points 7, 8 of the circuit 6, on the one hand, between which 7, 8 at least one electrical disturbance is generated and, on the other hand, other than the one 7 connected to the means 10 for generating at least one such disturbance.

Such a connection can be ensured either directly or, preferably, through an electronic casing 18, on the one hand, the device 5 includes and, on the other hand, which is associated with the electric circuit 6 or the latter 6 includes and, still on the other hand, connected to the first 12 and/or second 16 impedance.

As evoked above, the present invention will find a particular application in the field of the electrical installations comprised of electric, namely high-voltage lines. Such electric lines are usually of the overhead type, so that, in order to bring the electrode 14 into contact with a point 15 of such an installation 1, the device 5 should be brought close to this point 15. To this end and according to an additional feature of the invention, the device 5 is implanted at the end of an insulating pole aimed at being handled by an operator.

The invention also relates to a method for determining the characteristics of the electric voltage of an electrical installation 1 powered by a generator 2.

This method consists in:
generating at least one electrical disturbance between at least two points 7, 8 of an electric circuit 6 separated by a dielectric layer 9, this through means 10 for generating at least one disturbance between at least two of these points 7, 8;
measuring, at the terminals of a first impedance 12 this electric circuit 6 includes, a first electric current the creation of which is caused by the electrical disturbance or disturbances generated;
then bringing an electrode 14 associated with this electric circuit 6 (or the latter 6 includes) into contact with a point 15 of the electrical installation 1;
measuring, at the terminals of a second impedance 16 this electric circuit 6 includes and associated with this electrode 14, a second electric current created due to this bringing into contact;
measuring the evolution of the electric current at the terminals of the first impedance 12 due to this bringing into contact;
determining the characteristics of the electric voltage of the installation 1 based, on the one hand, on the evolution of the first electric current measured and, on the other hand, on the characteristics of the second electric current measured.

In this respect, it should be noted that the means 10 for generating at least one disturbance between at least two of these points 7, 8 are formed by a voltage generator 11 associated with the electric circuit 6 or the latter 6 includes.

According to another feature of this method, when at least one electrical disturbance is generated by the generator 11, through the latter 11 is generated a particular state of the material, namely a plasma, between at least two points 7, 8 of the electric circuit 6, in particular at the level of the dielectric layer 9.

In fact, when at least one electrical disturbance is generated by this generator 11, through the latter 1 are generated one or several electric arcs created between at least two points 7, 8 of the electric circuit 6.

In this respect, it should be noted that such a disturbance is generated between, on the one hand, a first point 7 of the circuit 6 connected to the generator 11 and, on the other hand, a second point 8 of the circuit 6 connected at least to the first impedance 12, even to the second impedance 16.

According to a particular embodiment and as evoked above, when at least one electrical disturbance is generated between at least two points 7, 8 of the circuit 6, this or these disturbances are generated between, on the one hand, one or several terminals (preferably a plurality of terminals) defined at the level of a first point 7 of the circuit 6 and, on the other hand, a second point 8, namely one or several terminals defined at the level of this second point 8.

A preferred embodiment consists in that at least one such disturbance (in particular at least one electric arc) is generated between, on the one hand, a plurality of terminals defined at the level of the first point 7 of the circuit 6 and, on the other hand, a second point 8 of this circuit 6, namely one or several terminals defined at the level of this second point 8.

In this respect, it should be noted that the plurality of terminals defined at the level of the first point 7 and/or the second point 8 allow generating a plurality of disturbances (namely one disturbance per terminal), which result into creating a plurality of induced currents in the first impedance 12.

As evoked above, a particular embodiment of the invention then consists in generating a positive disturbance and/or a negative disturbance (in particular a positive electric arc and/or a negative electric arc) between, on the one hand, one or several terminals defined at the level of the first point 7 and, on the other hand, one or several terminals defined at the level of the second point 8.

In particular, the invention can consist in generating, on the one hand, a positive disturbance between a first terminal defined at the level of the first point 7 and a second point 8 and, on the other hand, a negative disturbance between a second terminal defined at the level of the first point 7 and the second point 8.

Such an embodiment advantageously allows determining the polarity of the electric voltage of an installation 1 at a direct current, this based on the electric currents induced in the first 12 and second 16 impedances.

As evoked above, the device 5 includes, at the level of the second point 8 of this circuit 6, an electronic casing 18, on the one hand, associated with this circuit 6 or the latter includes and, on the other hand, connected to at least the first impedance 12, even the second impedance 16 this circuit 6 includes.

This being said, the invention then consists in that, when at least one electrical disturbance is generated between two points 7, 8 of the circuit 6, such a disturbance is generated between, on the one hand, a first point 7 of this circuit 6 and, on the other hand, said above-mentioned electronic casing 18.

1. Method for determining the characteristics of the electric voltage of an electric installation powered by a generator, wherein the method consists in
generating at least one electrical disturbance between at least two points of an electric circuit separated by a dielectric layer, this through a voltage generator associated with this electric circuit;
measuring, at the terminals of a first impedance this electric circuit includes, a first electric current the creation of which is caused by the electrical disturbance or disturbances generated;
then, bringing into contact an electrode associated with this electric circuit with a point of the electrical installation;
measuring, at the terminals of a second impedance this electric circuit includes and associated with this electrode, a second electric current created through this bringing into contact;
measuring the evolution of the first electric current at the terminals of the first impedance due to this bringing into contact;
determining the characteristics of the electric voltage of the installation based, on the one hand, on the evolution of the first electric current measured and, on the other hand, on the characteristics of the second electric current measured.

2. Method for determining the characteristics of the electric voltage of an electric installation according to claim 1, wherein, when an electrical disturbance is generated by the generator, through the latter is generated a particular state of the material, namely a plasma, between at least two points of the electric circuit.

3. Method for determining the characteristics of the electric voltage of an electric installation according to claim 1, wherein, when an electrical disturbance is generated by the generator, through the latter are generated one or several electric arcs created between at least two points of the electric circuit.

4. Method for determining the characteristics of the electric voltage of an electric installation according to claim 1, wherein, when at least one electrical disturbance is generated between two points of the electric circuit, such a disturbance is generated between, on the one hand, a first point of the circuit connected to the generator and, on the other hand, a second point of the circuit connected to at least the first impedance, even the second impedance.

5. Method for determining the characteristics of the electric voltage of an electric installation according to claim 1, wherein, when at least one electrical disturbance is generated between two points of the electric circuit, this or these disturbances are generated between, on the one hand, one or several terminals defined at the level of a first point of the circuit, namely formed by a first leg this circuit includes and, on the other hand, one or several terminals defined at the level of a second point of this circuit, namely formed by a second leg this circuit includes.

6. Method for determining the characteristics of the electric voltage of an electric installation according to claim 1, wherein, when at least one electrical disturbance is generated between two points of the electric circuit, such a disturbance is generated between, on the one hand, a first point of this circuit and, on the other hand, an electronic casing associated with this circuit or the latter includes, this at the level of a second point of this circuit.

7. Device for determining the characteristics of the electric voltage of an electric installation, wherein said device includes:
means for generating at least one electrical disturbance between at least two points of an electric circuit this device includes and which are separated by a dielectric layer;
means for measuring, at the terminals of a first impedance this electric circuit includes, a first electric current the creation of which is caused by the electrical disturbance or disturbances generated as well as the evolution of this first electric current;
an electrode, associated with this electric circuit, aimed at being brought into contact with a point of the electrical installation;
means for measuring, at the terminals of a second impedance the electric circuit includes and associated with said electrode, a second electric current created due to this bringing into contact;
means for determining the characteristics of the electric voltage of the installation based, on the one hand, on the evolution of the first electric current measured and, on the other hand, on the characteristics of the second electric current measured.

8. Device for determining the characteristics of the electric voltage of an electric installation according to claim 7, wherein the means for generating at least one electrical disturbance are formed by means capable of generating a particular state of the material, namely a plasma, between at least two points of the electric circuit.

9. Device for determining the characteristics of the electric voltage of an electric installation according to claim 7, wherein the means for generating at least one electrical disturbance are formed by means capable of generating at least one electric arc between at least two points of the electric circuit.

10. Device for determining the characteristics of the electric voltage of an electric installation according to claim 7, wherein the means for generating at least one electrical disturbance between at least two points of the circuit are connected to one or several terminals, at a first one of these points and/or at a second one of these points.

11. Device for determining the characteristics of the electric voltage of an electric installation according to claim 7, wherein the means for generating at least one electrical disturbance are formed by a voltage generator associated with the electric circuit and connected to at least one of the points between which at least one such electric disturbance is generated.

12. Device for determining the characteristics of the electric voltage of an electric installation according to claim 7, wherein the first impedance includes, on the one hand, a first terminal connected to the means for generating at least one electrical disturbance between at least two points of the circuit and, on the other hand, a second terminal connected to one of the points of the circuit, on the one hand, between which at least one electrical disturbance is generated and, on the other hand, other than the one connected to the means for generating at least one such disturbance.

13. Device for determining the characteristics of the electric voltage of an electric installation according to claim 7, wherein the second impedance includes, on the one hand, a first terminal connected to the electrode and, on the other hand, a second terminal connected to one of the points of the circuit, on the one hand, between which at least one electrical disturbance is generated and, on the other hand, other than the one connected to the means for generating at least one such disturbance.

14. Device for determining the characteristics of the electric voltage of an electric installation according to claim 7, wherein the device includes an electronic casing, associated with this circuit or the latter includes, and implanted at the level of one of the points of the circuit, on the one hand, between which at least one disturbance is generated and, on the other hand, other than the one connected to the means for generating at least one such disturbance.

15. Device for determining the characteristics of the electric voltage of an electric installation according to claim 7, wherein the device is implanted at the end of an insulating pole aimed at being handled by an operator.
